(19) United States
(12) Patent Application Publication
(10) Pub. No.: US 2023/0213395 A1
(43) Pub. Date: Jul. 6, 2023

(54) FLEXIBLE PIEZORESISTIVE SENSOR AND PREPARATION METHOD THEREOF

(71) Applicant: HARBIN INSTITUTE OF TECHNOLOGY, SHENZHEN, Guangdong Province (CN)

(72) Inventors: JUN WEI, GUANGDONG PROVINCE (CN); JINGJING LUO, GUANGDONG PROVINCE (CN); WEIWEI ZHAO, GUANGDONG PROVINCE (CN); FEIHUA LIU, GUANGDONG PROVINCE (CN)

(21) Appl. No.: 17/971,794

(22) Filed: Oct. 24, 2022

(30) Foreign Application Priority Data
Dec. 31, 2021 (CN) 202111675865.4

(51) Int. Cl. G01L 1/18

(52) U.S. Cl. CPC G01L 1/18

(57) ABSTRACT

The present application relates to the technical field of sensors, and in particular, to a flexible piezoresistive sensor and a preparation method thereof. The preparation method includes the following steps: cutting natural wood to obtain wood blocks; removing lignin and hemicellulose from the wood blocks to obtain an initial product; and connecting the initial product to an electrode, and conducting packaging to obtain the flexible piezoresistive sensor. The preparation method has the advantages of a wide range of raw materials, degradability, low cost, simple process, and industrial scale production, and the obtained product features excellent environmental friendliness, biocompatibility, designability, and flexibility, thereby providing a good application potential for a wearable device.

### CROSS REFERENCE TO RELATED APPLICATION

This patent application claims the benefit and priority of Chinese Patent Application No. 202111675865.4, filed on Dec. 31, 2021, the disclosure of which is incorporated by reference herein in its entirety as part of the present application.

### TECHNICAL FIELD

The present application relates to the technical field of sensors, and in particular, to a flexible piezoresistive sensor and a preparation method thereof.

### BACKGROUND ART

With the advent of artificial intelligence era, there is increasing demand for wearable devices, and piezoresistive, capacitive, piezoelectric and triboelectric devices made of various new materials are constantly emerging. The piezoresistive sensor is most widely used because of its unique features of simple manufacturing process, high sensitivity, and convenience in signal processing, etc.

As the most abundant plant resource on the earth, wood has rich water and nutrient transportation channels, and therefore may be regarded as a three-dimensional material with a certain pore structure. Cellulose, hemicellulose and lignin are three main components of wood, and the lignin is embedded between the cellulose and the hemicellulose as a hard binder. Therefore, by removing wood components such as the lignin, a relatively loose wood aerogel with obvious anisotropy and certain compressibility and resilience can be obtained.

A composite aerogel piezoresistive sensor with flexibility and conductivity can be obtained by using the abundant porous structure of the wood aerogel as a flexible substrate, supplemented with various conductive fillers including metals (particles/nanowires), carbon-based materials (carbon black, graphite, graphene, fullerenes, and carbon nanotubes), conductive polymers (PEDOT:PSS, polyacetylene, polyaniline, polypyrrole, etc.), new inorganic hybrids such as metal carbon/nitride Mxene with a two-dimensional layered structure, etc. However, it is difficult to disperse uniformly these conductive fillers in this kind of wood aerogel, which leads to a complicated preparation process and poor biocompatibility, and it is also challenging to balance the conflict between sensitivity and detection range of the final piezoresistive sensor. Although some researchers have proposed by direct carbonization or high-temperature pyrolysis to improve the compressibility, compression resilience and sensitivity of the wood aerogel sensor, unfortunately, inevitable brittleness and fragility of carbonized aerogel seriously affect practicality of the device.

### SUMMARY

An objective of the present application is to provide a flexible piezoresistive sensor and a preparation method thereof, which aim at solving the technical problem of how to prepare an all-wood flexible piezoresistive sensor without using conductive fillers at a low cost.

In order to achieve the foregoing application objective, the technical solutions of the present application are as follows:

According to a first aspect, the present application provides a preparation method of a flexible piezoresistive sensor, including the following steps:

cutting natural wood to obtain wood blocks;

removing lignin and hemicellulose from the wood blocks to obtain an initial product; and

connecting the initial product to an electrode, and conducting packaging to obtain the flexible piezoresistive sensor.

According to a second aspect, the present application provides a flexible piezoresistive sensor. The flexible piezoresistive sensor is prepared using the preparation method according to the present application.

The present application provides a pure bio-based flexible piezoresistive sensor and a preparation method thereof. The preparation method includes cutting the natural wood as raw material and removing lignin and hemicellulose to form an initial product mainly composed of lignocellulose, and the initial product is connected to electrode materials and packaged to obtain the final flexible piezoresistive sensor. The flexible piezoresistive sensor, with zero additions involved, can sensitively generate a resistance change based on the contact and separation of the lignocellulose in a compressing and releasing process. The preparation method has the advantages of a wide range of raw materials, degradability, low cost, and simple manufacturing process, and the obtained product features excellent environmental friendliness, biocompatibility, designability, and flexibility, thereby providing a good application potential for a wearable device.

### BRIEF DESCRIPTION OF THE DRAWINGS

To describe the technical solutions in the examples of the present application more clearly, the following briefly describes the accompanying drawings required for describing the examples. Apparently, the accompanying drawings in the following description show merely some examples of the present application, and those of ordinary skill in the art may still derive other accompanying drawings from these accompanying drawings without creative efforts.

FIG. 1 is a curve graph showing a current change rate of a flexible piezoresistive sensor prepared in Example 1 of the present application with stress;

FIG. 2 is a diagram showing the response time and recovery time of the flexible piezoresistive sensor prepared in Example 1 of the present application before and after a fixed pressure;

FIG. 3 is a schematic diagram showing cyclic stability performance of the flexible piezoresistive sensor prepared in Example 1 of the present application; and

FIG. 4 is a sensing performance test diagram of a flexible piezoresistive sensor made of graphene/wood composite aerogel used for a comparison in the present application.

### DETAILED DESCRIPTION OF THE EMBODIMENTS

To make the to-be-solved technical problems, technical solutions and beneficial effects of the present application clearer, the present application is further described in detail below with reference to examples. It should be understood that the specific examples described herein are merely intended to explain rather than to limit the present application.

In the present application, the term “and/or” describes associations between associated objects, and indicates three types of relationships. For example, “A and/or B” may indicate that A exists alone, A and B coexist, or B exists alone. “A” and “B” each may be singular or plural. The character “/” generally indicates that the associated objects are in an “or” relationship.

In the present application, “at least one” means one or more, and “a plurality of” means two or more. The term “at least one of the following” or a similar expression refers to any combination of these items, including any combination of single items or plural items.

It should be understood that, in various examples of the present application, sizes of sequence numbers of the foregoing processes do not imply the order of execution, and some or all steps may be executed in parallel or sequentially. The order of performing the processes should be determined based on their function and internal logic, and should not constitute any limitation to the implementation process of the examples of the present application.

Terms in the examples of the present application are merely used to describe the specific examples, and are not intended to limit the present application. The singular forms “a”, “the” and “this” used in the examples of the present application and the appended claims are also intended to include plural forms, unless the context clearly indicates other meanings.

The weight of related components mentioned in the specification of the examples of the present application may not only refer to the specific content of each component, but also indicate a proportional relationship between the weights of the components. Therefore, as long as the content of related components is scaled up or reduced according to the specification of the examples of the present application, it is within the scope disclosed in the specification of the examples of the present application. Specifically, the mass mentioned in the specification of the examples of the present application may be known mass units in the chemical industry, such as pg, mg, g, and kg.

The terms “first” and “second” are used only for description to distinguish objectives such as substances from each other, and should not be construed as indicating or implying relative importance or implying the number of indicated technical features. For example, without departing from the scope of the examples of the present application, a first XX may also be referred to as a second XX, and similarly, the second XX may also be referred to as the first XX. Thus, features defined with “first” and “second” may explicitly or implicitly include one or more of the features.

According to a first aspect of examples of the present application, a preparation method of a flexible piezoresistive sensor is provided. The preparation method includes the following steps.

S01: Cut natural wood to obtain wood blocks.

S02: Remove lignin and hemicellulose from the wood blocks to obtain an initial product.

S03: Connect the initial product to an electrode, and conduct packaging to obtain the flexible piezoresistive sensor.

Based on the exploration of the piezoresistive effect of a wood aerogel, on the one hand, the abundant porous structure of the wood aerogel provides excellent flexibility, compressibility and compression resilience, and thus the contact and separation of lignocellulose in the compression and resilience process lays a certain foundation for its own resistance change; and on the other hand, when the resistance of the wood aerogel is tested, a change rate of resistance is particularly significant. Therefore, in examples of the present application, natural wood as a raw material is cut and lignin and hemicellulose are removed to form an initial product mainly composed of lignocellulose, and the initial product is connected to an electrode and packaged to obtain the final flexible piezoresistive sensor without adding a conductive material. The preparation method has the advantages of a wide range of raw materials, degradability, low cost, simple process, and industrial scale production, and the obtained product features excellent environmental friendliness, biocompatibility, designability, and flexibility, thereby providing a good application potential for a wearable device.

In step S01, the natural wood as the raw material may be wood in nature, and may be, for example, Ochroma lagopus Swartz. Balsa wood is used in this example of the present application. The natural wood may be first washed (e.g., with water), then dried, and cut. The wood blocks obtained after cutting has a size of (0.5-2) cm×(0.5-2) cm×(0.5-2) cm. A wood block of this size may better undergo lignin and hemicellulose removal.

In step S02, the initial product obtained after lignin and hemicellulose removal may be a wood aerogel.

In an example, the step of removing lignin and hemicellulose includes: placing the cut wood blocks in a mixed solution containing sodium hydroxide and sodium sulfite for cooking, and sequentially conducting oxidative bleaching and drying to obtain the initial product. In this process, the cooking of the mixed solution containing sodium hydroxide and sodium sulfite may remove most of the lignin and a small part of hemicellulose in the wood, and oxidative bleaching may further remove the remaining lignin and hemicellulose.

Specifically, the wood blocks are placed in a mixed solution containing sodium hydroxide and sodium sulfite, with a solid-liquid ratio of 1 g:(15-40) mL, and a molar ratio of the sodium hydroxide and the sodium sulfite in the mixed solution is 2.5:(0.4-1). Under this condition, the wood may be fully soaked for better treatment with alkali. The cooking is conducted at 100-105° C. for 1-15 h. Under this condition, the lignin may be better removed.

Specifically, the step of oxidative bleaching includes cooking and bleaching at 80-100° C. by using a hydrogen peroxide diluent with a concentration of 1.5-2.5 mol/L. The cooking time is subject to the final complete whitening of a sample. Under this condition, the oxidative bleaching has a better effect of removing the remaining lignin and hemicellulose. Before the oxidative bleaching, the alkali-treated sample may be washed with deionized water to neutrality; and after washing, the sample is soaked and cooked in a 1.5-2.5 mol/L hydrogen peroxide diluent (which may be obtained by diluting hydrogen peroxide with a mass fraction of 30%).

Specifically, the drying is vacuum freeze drying conducted at −60° C. to −40° C. for 36-48 h. Wood aerogels with different densities and porosities may be obtained through the vacuum freeze drying.

In an example, the step of removing lignin and hemicellulose includes: placing the wood blocks in an aqueous solution containing sodium chlorite and acetic acid for primary soaking, then placing the wood blocks in a sodium hydroxide solution for secondary soaking, and drying the wood blocks to obtain the initial product. The primary soaking under an acid condition may remove the lignin, and the secondary soaking under an alkali condition may remove the hemicellulose.

Specifically, the primary soaking is conducted at 75-85° C. for 4-6 h. Under the condition, the soaking effect is better. The wood blocks, the sodium chlorite and the water may be at a mass ratio of 1:1:20. The pH of the aqueous solution is adjusted to 3-4.7 by adding the acetic acid, and the same number of parts of sodium chlorite as an initial condition and appropriate acetic acid are added every 1-1.5 h during the period, to keep the pH stable before and after the primary soaking.

Specifically, the secondary soaking is conducted at 80-100° C. for 8-12 h. Under the condition, the soaking effect is better. Before the secondary soaking, the sample having undergone the primary soaking may be washed to neutrality with deionized water, and soaked in 1-2.5 mol/L sodium hydroxide solution for hemicellulose removal.

Specifically, the drying is vacuum freeze drying conducted at −60° C. to −40° C. for 36-48 h. Wood aerogels with different densities and porosities may be obtained through the vacuum freeze drying.

In an example, the step of removing lignin includes placing the wood blocks in a sterilized nutrient agar medium, inoculating strains for incubation and culture, then removing bacteria, and sterilizing and drying the wood blocks to obtain the initial product, where the strain includes at least one selected from the group consisting of white rot fungi, Panus conchatus, Coriolus versicolor, Pleurotus ostreatus, Fomes lignosus, and Ganoderma applanatum. In this example of the present application, the lignin may be removing by using a biological method, and may be degraded by using microorganisms of the foregoing strains and enzymes produced thereby, which has the advantages of raw material saving, energy consumption reduction, and low pollution load. A method for obtaining an all-wood piezoresistive sensor by using a biological method is provided. The biological method is to properly degrade lignin in wood by using lignin-degrading microorganisms. Because lignin removal by using the biological method takes a relatively long time and is relatively thorough, and the structure of the material is loose enough, compared with a chemical method, the biological method does not need oxidative bleaching subsequently, but, certainly, proper bleaching may still be conducted based on actual needs.

Specifically, in the step of removing bacteria, fungi may be removed from the wood surface with a brush. In the step of sterilization, sterilization may be conducted at 120-121° C. for 25-30 min. In the step of drying, the drying may be conducted at 100-103° C. for 20-24 h.

In an example, the process of removing bacteria, and sterilizing and drying the wood blocks includes: removing the fungi from the wood surface with a brush, then placing the sample in a temperature-resistant and pressure-resistant closed container, treating the sample in an autoclave at 120-121° C. for 25-30 min, cooling the sample to room temperature (25-27° C.), and finally drying the sample in an oven at 100-103° C. for 20-24 h.

Specifically, the step of incubation and culture includes incubation at 21-23° C. and relative humidity of 68%-72% for 2-24 weeks in the dark. Under this condition, the degradation effect is better.

Step S03 is a process of forming a finished product from the initial product. Specifically, S03 includes connecting copper foil as the electrode to the initial product by using silver paste, then drawing out a copper wire from the copper foil, and integrally packaging with a polydimethylsiloxane film. The copper foil may be used as an anode and a cathode.

According to a second aspect of the examples of the present application, a flexible piezoresistive sensor is provided. The flexible piezoresistive sensor is prepared by using the foregoing preparation method according to this example of the present application.

The flexible piezoresistive sensor according to this example of the present application is a purely bio-based flexible piezoresistive sensor. The flexible piezoresistive sensor can sensitively generate a resistance change based on the contact and separation of the lignocellulose in a compression and resilience process, thereby forming a flexible piezoresistive sensor without adding a conductive material. The flexible piezoresistive sensor has excellent sensing performance, excellent environmental friendliness, biocompatibility, designability (may be cut, bent and folded for different shapes based on use requirements) and flexibility, which provides a development opportunity and application potential for wearable devices and a new opportunity and starting point for the design and material selection of flexible sensing devices.

Description will be provided below with reference to specific examples.

### Example 1

A preparation method of a flexible piezoresistive sensor includes the following steps.

1. Cutting of Natural Wood

Natural wood, balsa wood, was washed, dried and cut to form wood blocks with a size of 1 cm×1 cm×1 cm.

2. Removal of Lignin and Hemicellulose

2.1 Alkali Treatment

10 g of cut wood blocks was taken, and soaked in a mixed solution containing NaOH/Na₂SO₃ at a solid-liquid ratio of 1 g:20 mL for cooking. In the mixed solution, the concentration of NaOH was 2.5 mol/L and the concentration of Na₂SO₃ was 1 mol/L; and the cooking was conducted at 100° C. for 10 h. This process could remove most lignin and a small part of hemicellulose from the wood.

2.2 Oxidative Bleaching

The cooked sample was washed with deionized water to neutrality, and soaked in a hydrogen peroxide diluent and continued to be cooked until the sample turned white. The concentration of the hydrogen peroxide diluent was 2.5 mol/L, and the cooking was conducted at 100° C. The objective of oxidative bleaching was to further remove the remaining lignin and hemicellulose from the sample.

2.3 Drying

The obtained sample was dried by vacuum freeze drying at about −50° C. for 40 h, and finally an obtained initial product was a wood aerogel.

3. Device Packaging

Two pieces of copper foil were used as anode and cathode materials respectively, and the two pieces of copper foil were connected to the obtained wood aerogel sample through silver paste. In addition, copper wires were drawn out from the copper foil in an electric welding manner, and finally, overall packaging was conducted by using a polydimethylsiloxane (PDMS) film.

### Example 2

A preparation method of a flexible piezoresistive sensor includes the following steps.

1. Cutting of Natural Wood

Natural wood, balsa wood, was washed, dried and cut to form wood blocks with a size of 1 cm×1 cm×1 cm.

2. Removal of Lignin and Hemicellulose

2.1 Acid Soaking

10 g of cut wood blocks was taken, and soaked in a sodium chlorite/acetic acid aqueous solution at a ratio of mass fractions of wood, sodium chlorite and water being 1:1:20 for soaking at 80° C. for 5 h to remove lignin; the added acetic acid adjusted the pH of the solution to 3-4.7, and the same number of parts of sodium chlorite as an initial condition and appropriate acetic acid were added every 1 h during the period, to keep the pH stable before and after the soaking.

2.2 Alkali Soaking

The sample obtained by the acid soaking was first washed with deionized water to neutrality, and soaked in 2 mol/L sodium hydroxide solution to remove hemicellulose, and the soaking was conducted at 90° C. for 10 h.

2.3 Drying

The obtained sample was dried by vacuum freeze drying at about −60° C. for 38 h, and finally an obtained initial product was a wood aerogel.

3. Device Packaging

Two pieces of copper foil were used as anode and cathode materials respectively, and the two pieces of copper foil were connected to the obtained wood aerogel sample through silver paste. In addition, copper wires were drawn out from the copper foil in an electric welding manner, and finally, overall packaging was conducted by using a PDMS film.

### Example 3

A preparation method of a flexible piezoresistive sensor includes the following steps.

1. Cutting of Natural Wood

Natural wood, balsa wood, was washed, dried and cut to form wood blocks with a size of 1 cm×1 cm×1 cm.

2. Removal of Lignin

2.1 Disinfection and Sterilization

The cut wood blocks were disinfected with ethylene oxide, and the initial total amount of wood blocks which was 10 g was recorded. A culture dish used for strain inoculation was sterilized at a high temperature of 121° C. for 20 min. A microorganism used to degrade lignin was white rot fungi.

2.2 Strain Incubation

75 mL of 4% nutrient agar (MEA) was placed into the culture dish sterilized at high temperature. The wood blocks sample was put in the culture dish, and newly inoculated strain aphides were put in the culture dish and incubated in a dark condition at 22° C. and relative humidity of 70%. After incubation for 15 weeks, fungi were removed from the wood surface with a brush, and the sample was placed in a temperature-resistant and pressure-resistant closed container, treated in an autoclave at 121° C. for 30 min, cooled to room temperature, and finally dried in an oven at 103° C. for 24 h.

3. Device Packaging

Two pieces of copper foil were used as anode and cathode materials respectively, and the two pieces of copper foil were connected to the obtained wood aerogel sample through silver paste. In addition, copper wires were drawn out from the copper foil in an electric welding manner, and finally, overall packaging was conducted by using a PDMS film.

Performance Testing

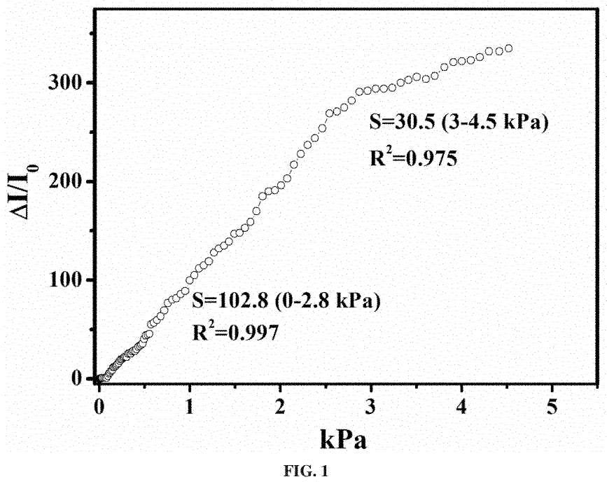

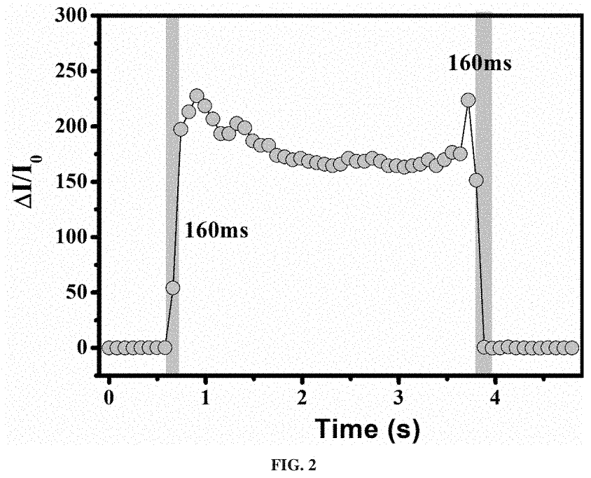

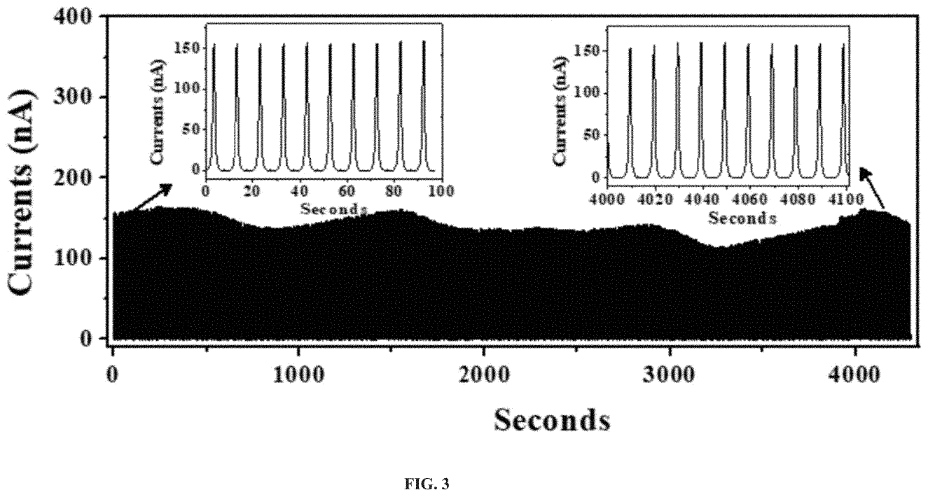

Taking Example 1 as an example, test results are shown in FIGS. 1 to 3. In FIG. 1, when the compressive stress was 5 kPa, stress sensitivity of the flexible piezoresistive device was as high as 102.8 kPa⁻¹, and the linear range limit could reach 2.8 kPa (la). In FIG. 2, under the same conditions, the response time did not exceed 200 ms. In FIG. 3, cyclic stability of the flexible piezoresistive device was tested under high compressive strain of 85% and a compression frequency of 0.1 Hz. It was found that the device still maintained relatively stable current output performance after cyclic testing for 400 times. Further, in FIG. 3, two upper enlarged charts corresponding to two part of the lower chart, namely the first 10 tests and the last 10 tests respectively, are presented to clearly illustrate a relationship between the currents and the seconds. Therefore, the flexible piezoresistive sensor has good sensing performance and short-term durability.

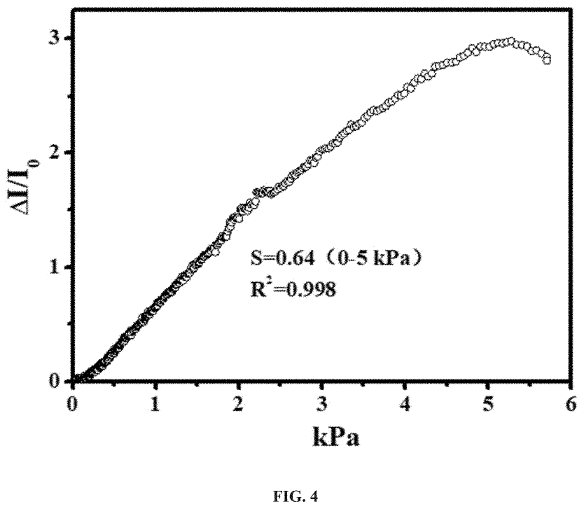

Based on the foregoing obtained wood aerogel, different conductive fillers such as graphene, carbon nanotubes, Mxene, and PEDOT:PSS can be introduced to obtain additive composite flexible piezoresistive devices. Taking graphene as an example, graphene oxide was first ultrasonically dispersed in ethanol to obtain a graphene dispersion with a certain mass fraction. Then, the wood aerogel was soaked in the dispersion, and imbibition was conducted under a vacuum condition. This process was completed in a vacuum drying oven at room temperature. Then, the samples were freeze-dried to obtain graphene-wood aerogel composite flexible piezoresistive sensors with different mass fractions. Under the same mechanical conditions, the samples were tested, and results are shown in FIG. 4. Compared with that of Example 1, a flexible piezoresistive sensor composited by adding graphene had stress sensitivity much lower than that of a flexible piezoresistive sensor sample using a pure aerogel. This indicates that the pure wood aerogel itself may be used as a piezoresistive sensor to implement relatively high sensitivity.

The above described are merely preferred examples of the present application, and are not intended to limit the present application. Any modification, equivalent substitution, improvement, etc. without departing from the spirit and principle of the present application should fall within the protection scope of the present application.

What is claimed is:

1. A preparation method of a flexible piezoresistive sensor, comprising the following steps:
cutting natural wood to obtain wood blocks;
removing lignin and hemicellulose from the wood blocks to obtain an initial product; and
connecting the initial product to an electrode, and conducting packaging to obtain the flexible piezoresistive sensor.

2. The preparation method according to claim 1, wherein the step of removing lignin and hemicellulose comprises: placing the wood blocks in a mixed solution containing sodium hydroxide and sodium sulfite for cooking, and conducting oxidative bleaching and drying to obtain the initial product.

3. The preparation method according to claim 2, wherein the wood blocks are placed in a mixed solution containing sodium hydroxide and sodium sulfite, with a solid-liquid ratio of 1 g:(15-40) mL, and a molar ratio of the sodium hydroxide and the sodium sulfite in the mixed solution is 2.5:(0.4-1); and/or
the cooking is conducted at 100-105° C. for 1-15 h; and/or
the oxidative bleaching comprises cooking and bleaching at 80-100° C. by using a hydrogen peroxide diluent with a concentration of 1.5-2.5 mol/L; and/or
the drying is vacuum freeze drying conducted at −60° C. to −40° C. for 36-48 h.

4. The preparation method according to claim 1, wherein the step of removing lignin and hemicellulose comprises: placing the wood blocks in an aqueous solution containing sodium chlorite and acetic acid for primary soaking, placing the wood blocks in a sodium hydroxide solution for secondary soaking, and drying the wood blocks to obtain the initial product.

5. The preparation method according to claim 4, wherein the primary soaking is conducted at 75-85° C. for 4-6 h; and/or
the secondary soaking is conducted at 80-100° C. for 8-12 h; and/or
the drying is vacuum freeze drying conducted at −60° C. to −40° C. for 36-48 h.

6. The preparation method according to claim 1, wherein the step of removing lignin comprises placing the wood blocks in a sterilized nutrient agar medium, inoculating strains for incubation and culture, removing bacteria, and sterilizing and drying the wood blocks to obtain the initial product, wherein the strain comprises at least one selected from the group consisting of white rot fungi, Panus conchatus, Coriolus versicolor, Pleurotus ostreatus, Fomes lignosus, and Ganoderma applanatum.

7. The preparation method according to claim 6, wherein the step of incubation and culture comprises incubation at 21-23° C. and relative humidity of 68%-72% for 2-24 weeks in the dark; and/or
the sterilization is conducted at 120-121° C. for 25-30 min; and/or
the drying is conducted at 100-103° C. for 20-24 h.

8. The preparation method according to claim 1, wherein the natural wood is Ochroma lagopus Swartz, and the wood blocks obtained after cutting has a size of (0.5-2) cm×(0.5-2) cm×(0.5-2) cm.

9. The preparation method according to claim 2, wherein the natural wood is Ochroma lagopus Swartz, and the wood blocks obtained after cutting has a size of (0.5-2) cm×(0.5-2) cm×(0.5-2) cm.

10. The preparation method according to claim 3, wherein the natural wood is Ochroma lagopus Swartz, and the wood blocks obtained after cutting has a size of (0.5-2) cm×(0.5-2) cm×(0.5-2) cm.

11. The preparation method according to claim 1, wherein the step of connecting the initial product to an electrode, and conducting packaging comprises connecting copper foil as the electrode to the initial product by using silver paste, drawing out a copper wire from the copper foil, and conducting integrally packaging with a polydimethylsiloxane film.

12. A flexible piezoresistive sensor, wherein the flexible piezoresistive sensor is prepared by using the preparation method according to claim 1.

13. The flexible piezoresistive sensor according to claim 12, wherein the step of removing lignin and hemicellulose comprises: placing the wood blocks in a mixed solution containing sodium hydroxide and sodium sulfite for cooking, and conducting oxidative bleaching and drying to obtain the initial product.

14. The flexible piezoresistive sensor according to claim 13, wherein the wood blocks are placed in a mixed solution containing sodium hydroxide and sodium sulfite, with a solid-liquid ratio of 1 g:(15-40) mL, and a molar ratio of the sodium hydroxide and the sodium sulfite in the mixed solution is 2.5:(0.4-1); and/or
the cooking is conducted at 100-105° C. for 1-15 h; and/or
the oxidative bleaching comprises cooking and bleaching at 80-100° C. by using a hydrogen peroxide diluent with a concentration of 1.5-2.5 mol/L; and/or
the drying is vacuum freeze drying conducted at −60° C. to −40° C. for 36-48 h.

15. The flexible piezoresistive sensor according to claim 12, wherein the step of removing lignin and hemicellulose comprises: placing the wood blocks in an aqueous solution containing sodium chlorite and acetic acid for primary soaking, placing the wood blocks in a sodium hydroxide solution for secondary soaking, and drying the wood blocks to obtain the initial product.

16. The flexible piezoresistive sensor according to claim 15, wherein the primary soaking is conducted at 75-85° C. for 4-6 h; and/or
the secondary soaking is conducted at 80-100° C. for 8-12 h; and/or
the drying is vacuum freeze drying conducted at −60° C. to −40° C. for 36-48 h.

17. The flexible piezoresistive sensor according to claim 12, wherein the step of removing lignin comprises placing the wood blocks in a sterilized nutrient agar medium, inoculating strains for incubation and culture, removing bacteria, and sterilizing and drying the wood blocks to obtain the initial product, wherein the strain comprises at least one selected from the group consisting of white rot fungi, Panus conchatus, Coriolus versicolor, Pleurotus ostreatus, Fomes lignosus, and Ganoderma applanatum.

18. The flexible piezoresistive sensor according to claim 17, wherein the step of incubation and culture comprises incubation at 21-23° C. and relative humidity of 68%-72% for 2-24 weeks in the dark; and/or
the sterilization is conducted at 120-121° C. for 25-30 min; and/or
the drying is conducted at 100-103° C. for 20-24 h.

19. The flexible piezoresistive sensor according to claim 12, wherein the natural wood is Ochroma lagopus Swartz, and the wood blocks obtained after cutting has a size of (0.5-2) cm×(0.5-2) cm×(0.5-2) cm.

20. The flexible piezoresistive sensor according to claim 12, wherein the step of connecting the initial product to an electrode, and conducting packaging comprises connecting copper foil as the electrode to the initial product by using silver paste, drawing out a copper wire from the copper foil, and conducting integrally packaging with a polydimethylsiloxane film.
